(19) United States
(12) Patent Application Publication
(10) Pub. No.: US 2011/0211310 A1
(43) Pub. Date: Sep. 1, 2011

(54) SIGNAL PATH INTERCONNECTION AND ASSEMBLY

(75) Inventors: Duane James Farling, Lakeville, MN (US); Nathan Loren Lester, Minneapolis, MN (US); Neal Frank Gunderson, Lake Elmo, MN (US); Raymond Pavlak, JR., Shrewsbury, MA (US)

(73) Assignee: SEAGATE TECHNOLOGY LLC, Scotts Valley, CA (US)

(21) Appl. No.: 12/715,009

(22) Filed: Mar. 1, 2010

(51) Int. Cl. G06F 1/16; H05K 7/00

(52) U.S. Cl. 361/679.31; 361/748

(57) ABSTRACT

Various embodiments are generally directed to an apparatus that provides an interconnection with efficient data signal throughput. In some embodiments, a controller printed circuit board (PCB) supports a controller integrated circuit (IC) and a support bracket. A memory PCB is supported by the support bracket in a spaced apart, parallel relation to the controller PCB. The memory PCB supports at least one memory IC and has an edge connector which engages the support bracket. A flex circuit is provided that interconnects the edge connector to an interposer positioned on the controller PCB between the respective areal extent of the controller PCB and the memory PCB to form a data signal path between the memory IC and the controller IC.

### SUMMARY

Various embodiments of the present invention are generally directed to an apparatus associated with forming a signal path in a data storage device.

In accordance with various embodiments, a controller printed circuit board (PCB) supports a controller integrated circuit (IC) and a support bracket. A memory PCB is supported by the support bracket in a spaced apart, parallel relation to the controller PCB. The memory PCB supports at least one memory IC and has an edge connector which engages the support bracket. A flex circuit is provided that interconnects the edge connector to an interposer positioned on the controller PCB between the respective areal extent of the controller PCB and the memory PCB to form a data signal path between the memory IC and the controller IC.

These and various other features and advantages which characterize the various embodiments of the present invention can be understood in view of the following detailed discussion and the accompanying drawings.

### BRIEF DESCRIPTION OF THE DRAWINGS

FIG. 1 is a generalized functional representation of an exemplary data storage device constructed and operated in accordance with various embodiments of the present invention.

FIG. 2 shows an exemplary embodiment of the data storage device of FIG. 1.

FIG. 3 generally illustrates a controller PCBA constructed in accordance with various embodiments of the present invention.

FIG. 4 displays a side view of an exemplary controller PCBA.

FIG. 5 shows a side view of an exemplary controller PCBA.

FIG. 6 generally illustrates an exemplary controller PCBA in accordance with various embodiments of the present invention.

FIGS. 7A and 7B illustrate a top view of an exemplary controller PCBA in accordance with various embodiments of the present invention.

FIGS. 8A and 8B display an exemplary controller PCBA in accordance with various embodiments of the present invention.

FIG. 9 provides an exemplary board edge connector as constructed and operated in accordance with various embodiments of the present invention.

FIG. 10 shows a cut-away view of an exemplary controller PCBA in accordance with various embodiments of the present invention.

FIG. 11 generally illustrates an exemplary support bracket in accordance with various embodiments of the present invention.

### DETAILED DESCRIPTION

A continuing trend in modern electronics devices and especially in data storage devices is increasing data capacity and transmission rates while reducing component size. Such trend has made enhancing signal transmission strength increasingly burdensome due to the intricate structure of the electrical connectors and the magnetic nature of electrical signals. As such, data transmitting components have been configured for reliability at the expense of transmission speed.

Accordingly, a need exists for data transmitting structure that can support both small form factors as well as high data throughput. A controller printed circuit board (PCB) that includes at least a controller integrated circuit (IC) and a support bracket can provide such high data throughput by connecting the controller PCB to at least one memory PCB via a flex circuit. Use of the support bracket can provide a small form factor in part due to the ability to maintain the memory PCB in a parallel relation to the controller PCB while engaging an edge connector of the memory PCB. Interconnecting the edge connector with an interposer positioned between the areal extent of the controller PCB and the memory PCB can further provide a robust and reliable signal path capable of high data transfer rates.

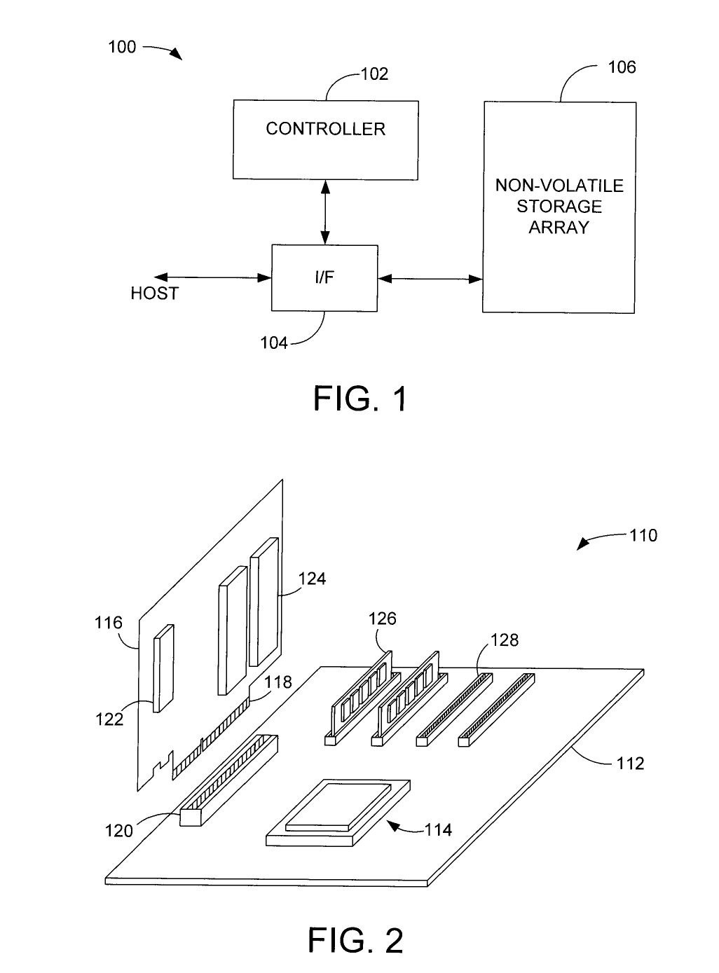

In FIG. 1, a functional block representation of an exemplary data storage device 100 is provided. While not limiting, for purposes of the present discussion it will be contemplated that the device 100 is characterized as a solid-state drive (SSD) that utilizes Flash memory cells arranged in a NAND configuration.

The device 100 includes a top level controller 102, an interface (I/F) circuit 104 and a non-volatile data storage array 106. The I/F circuit 104 operates under the direction of the controller 102 to transfer user data between the array 106 and a host device (not shown). In some embodiments, the controller 102 is a programmable microcontroller, while in other embodiments, data can be buffered in the I/F circuit 104 pending a transfer of the data between the array 106 and the host device

FIG. 2 generally illustrates a exemplary representation of a data storage device 110 in accordance with various embodiments of the present invention. The device 110 can have a printed circuit board assembly (PCBA) that supports at least an overall controller 114 that is capable of communicating with various other components of the device 110. One such component can be a controller PCB 116 that is connected to the PCBA via an edge connector 118 and a slot receiver 120. While not limiting, the controller PCB 116 can be configured with a controller IC (not shown) that connects a PCB controller 122 to a memory PCB 124. In some embodiments, the controller PCB is characterized as a PCIe card that conforms to specific size and connectivity standards set by industry.

The PCBA 112 can further include one or more volatile or non-volatile memory chips 126 that connect to the overall controller 114 via chip receivers 128. The device 110 can provide various data operations while maintaining a small size. However, high data capacity and transmission rates become increasing difficult to attain as aspects of the PCBA reduce in size.

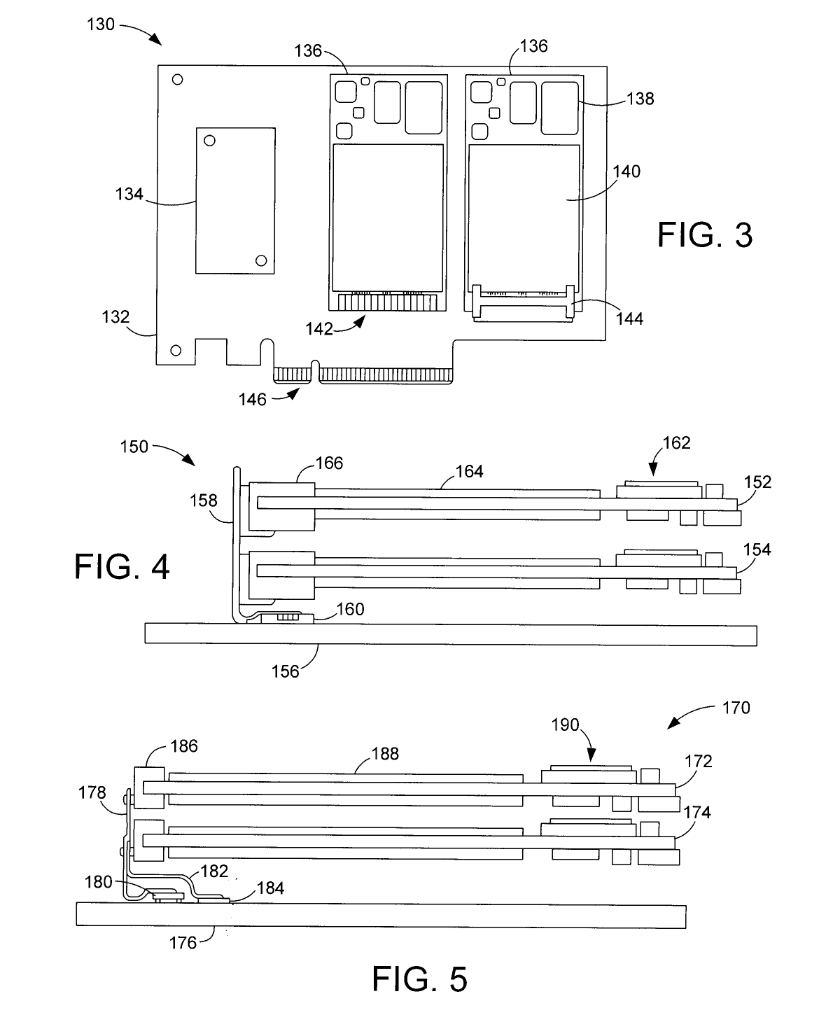

FIG. 3 shows a top view of an exemplary controller PCBA 130 in accordance with various embodiments of the present invention. A controller PCB 132 is shown configured to support and interconnect a controller 134 and a plurality of memory PCBs 136 via one or more integrated circuits (IC). In various embodiments, the memory PCBs 136 can each be configured with unique characteristics and components, but may also be identical in having the same physical dimensions and operational components 138.

One such operational component can be a memory region 140 that encompasses one or more memory chips. It is contemplated that the memory chips are non-volatile solid state devices (SSD), such as Flash memory, but such configuration is not required or limited. The memory PCB 136 can connect to the controller PCB 132 via connection pads 142 that correspond to the various operational components 138 and a translating board edge connector 144. The controller PCB 132 can then transfer signals to another structure, such as the PCBA of FIG. 2, via controller connection pads 146 that correspond to the integrated circuits found on the controller PCB 132.

FIG. 4 displays a side view of another controller PCBA 150 constructed in accordance with various embodiments of the present invention. A first and second memory PCB 152 and 154 are vertically stacked above a controller PCB 156 in a spaced apart and parallel relationship with the controller PCB 156. The memory PCBs are also each connected with a flex circuit 158 that interconnects with the controller PCB 156 via an interposer 160. In some embodiments, the flex circuit 158 is affixed and connected to spring contacts of the interposer 160 that allow subsequent removal and installation of flex circuits. Such connections can provide for selective removal and replacement of memory PCBs to allow repair and upgrading of the operational characteristics of the controller PCBA 150

As shown, the flex circuit 158 forms a data signal path that connects the operational components 162 and memory portion 164 of each memory PCB 152 and 154 to the controller PCB 156 via a translating board edge connector 166, such as an SATA/SAS connector. While not limiting, the flex circuit 158 can be coupled to the board edge connector 166 in a variety of ways that include spring contacts, solder, and tension mounts. Furthermore, the flex circuit 158 can engage one or more sides of the memory PCB 152 to enable a stable interconnection of the connection pads, such as the pads 142 of FIG. 3, that correspond to the memory IC of the particular PCB. As such, the board edge connector 166 can translate the connection pads of the memory PCB to data transmission pathways of the flex circuit 158 and provide data signal paths that are capable of high data throughput and efficiency.

While the interconnection of the memory PCB and the flex circuit 158 can be made through a translating connector 166, such configuration is not required as any connection means can be used to allow communication between the memory PCB and the controller PCB. Likewise, the use of an interposer 160 is not limited and can be modified or changed as desired. For example, the flex circuit may be connected to the memory PCB through a slot receiver and to the controller PCB via a soldered connection. In some embodiments, the flex circuit 158 comprises signal transmission paths capable of data input and output of at least 12 Gigabits per second.

An exemplary embodiment of a controller PCBA 170 is illustrated in FIG. 5 with a plurality of flex circuits that independently form data signal pathways between memory PCBs and a controller PCB. As generally illustrated, but not in a limiting fashion, a first and second memory PCB 172 and 174 that each contains at least one memory IC that is interconnected to a controller PCB 176 via a flex circuit and an interposer. That is, a first flex circuit 178 can interconnect a memory IC of the first memory PCB with the controller PCB 176 through a connection with a first interposer 180 that is positioned within the areal extent of the first and second memory PCB 172 and 174. Similarly, a second independent interconnection can be formed by connecting a second flex circuit 182 to a second interposer 184.

As displayed in FIG. 4, operational components and board edge connectors can occupy a significant portion of the usable surface area of the memory PCB. A reduction in the size of the board edge connector, as shown by the board edge connector 186 in FIG. 5, can increase the capacity and operation of the memory PCB. In operation, the board edge connector 186 can be modified to occupy a predetermined surface area so that a maximum amount of memory 188 can be installed on the memory PCB while providing ample space for operational components 190 to be properly installed.

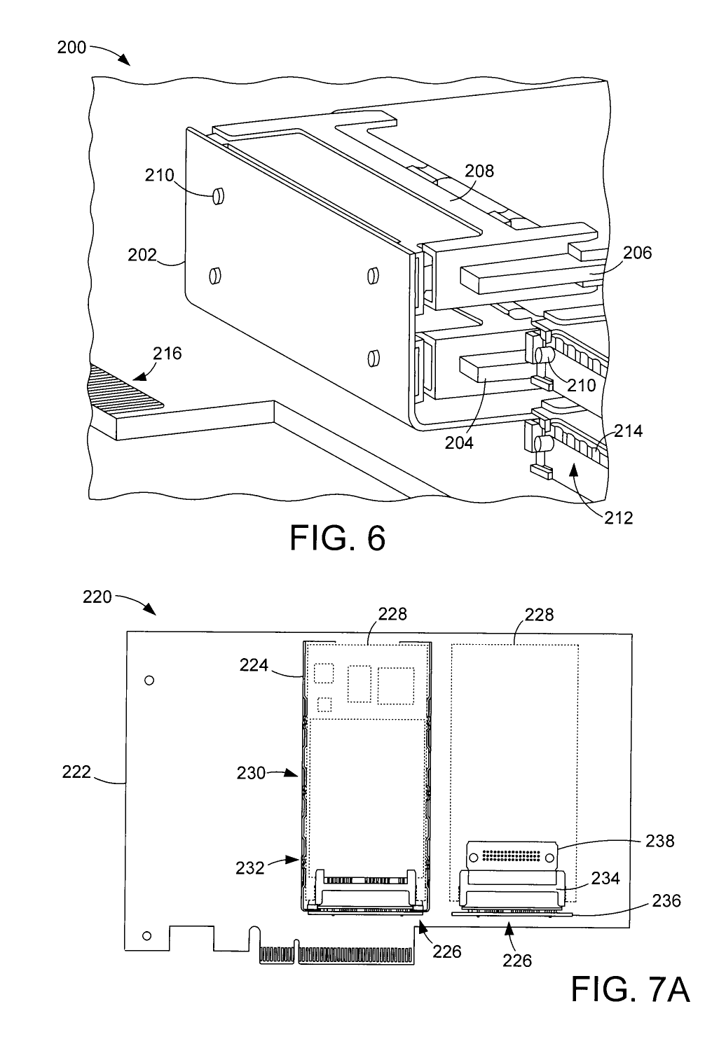

In FIG. 6, a portion of an exemplary controller PCBA 200 is shown as constructed in accordance with various embodiments of the present invention. A flex circuit 202 is connected to a first and second memory PCB 204 and 206 through translating board edge connectors 208 that engage a memory board edge connector. In some embodiments, the board edge connector 208 engages both a top and bottom side of the memory PCB to securely engage the memory board edge connector and provide a reliable electrical connection between the memory IC of the memory PCB. The translating board edge connector 208 can further be coupled to the flex circuit 202 with connecting posts 210 that extend through predetermined portions of the flex circuit 172 and maintain the flex circuit 202 in proper alignment with the board edge connector 208.

For illustrative purposes, the translating board edge connectors 212 are shown disconnected from any flex circuit to display the connecting wires 214 that correspond to portions of the memory IC. As shown in FIG. 6, a single flex circuit 202 is aligned and connected to both the first and second memory PCB 204 and 206 to form a data signal path from the respective memory ICs to the controller PCB and the controller connection pads 216 that can be configured to communicate with an external host. In some embodiments, he flex circuit houses a plurality of connective pathways along a single plane and isolates the each pathway with a polymer material. Such construction can allow for movement of the flex circuit without disturbing a data signal carrying capabilities of the conductive pathways in combination with providing various magnetic and electrostatic shielding characteristics.

It should be noted that the translating board edge connector 212 may include a variety of different connecting mechanisms that provide interconnection between a flex circuit and the components of the memory PCB. In various embodiments, the memory PCB's can be selectively engaged and disengaged by one or more flex circuits with board edge connectors, as desired, to allow a variety of interconnection possibilities between the memory PCBs and the controller PCB. However, as can be appreciated, the flex circuit 202 and board edge connector 212 cannot sustain one or more memory PCBs in a spaced apart, parallel relationship with the controller PCB.

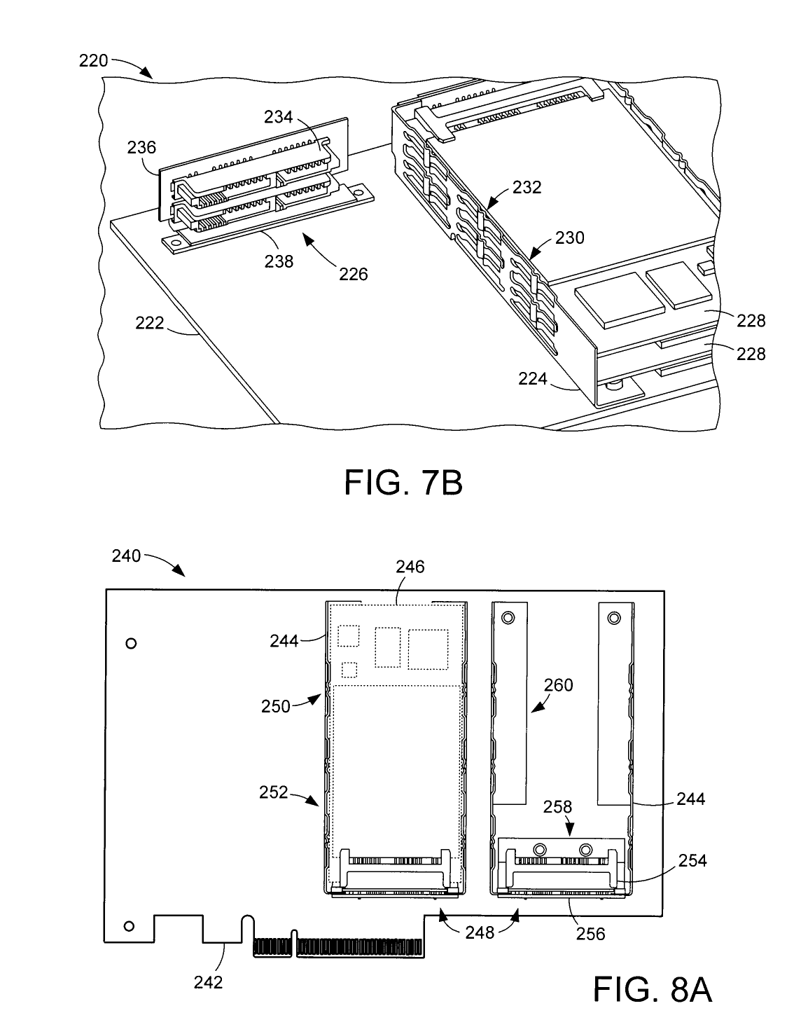

FIGS. 7A and 7B generally illustrate a controller PCBA 220 that includes a support bracket configured to engage, align, and support one or more memory PCBs. The controller PCB 222 is affixed to a support bracket 224 that engages a connection assembly 226 to allow one or more memory PCBs to be connected to the controller PCB 222. In FIG. 7A, a top plan view of the controller PCBA 220 is displayed with multiple memory PCBs 228 segmented for illustrative purposes. The support bracket 224 is configured to engage the controller PCB 222, at least one memory PCB 228, and the connection assembly 226 to maintain the memory PCB 228 in a predetermined relationship with the controller PCB 222 and provide a secure data signal path from the memory IC of each memory PCB 228 to the controller IC of the controller PCB 222.

The spaced apart, parallel relationship between the memory PCB 228 and the controller PCB 222 can be facilitated by features in the support bracket 224 that engage localized areas of the memory PCB 228. That is, top retention features 230 can be configured to engage a specified region of the memory PCB 228 that is less than the length of the memory PCB. For example, the top retention features 230 can engage the memory PCB 228 exclusively on one side and an area that is less than the available surface area of the memory PCB 228. In addition, side retention features 232 can be included in the support bracket 224 to engage localized areas of the side of a memory PCB 228 to maintain the memory PCB's position despite vibration, heat, and abuse imposed on the controller PCB 222.

In the exemplary embodiment shown in FIGS. 7A and 7B, a series of top and side retention features 230 and 232 are adjacently positioned to engage a plurality of localized areas of the top and side of the memory PCB 228. Such configuration can allow the memory PCB 228 to move and even disengage from one retention feature while maintaining a predetermined position, relationship, and connection with the controller PCB 222. The support bracket 224 can concurrently maintain a connection assembly 226 in a predetermined position with respect to both the controller and memory PCBs 222 and 228.

It should be noted that the connection assembly 226 is not limited to a certain number, type, or configuration, but form the interconnection between the memory IC and the controller IC. The assembly 226 can include one or more board edge connectors 234 that are affixed to a flex circuit 236 that is subsequently connected to an interposer 238 that is resident on the controller PCB 222. Engagement of the connection assembly 226 with the support bracket 224 can reliably provide a physically and electrically secure engagement of the memory PCB 228 while allowing for selective disengagement for various purposes, such as repair, reworking, and replacement of the memory PCB.

As displayed in FIG. 7B, the vertical configuration of the support bracket 224 is provided in accordance with some embodiments of the present invention. The support bracket 224 can be configured to maintain numerous memory PCBs 228 in a spaced apart, parallel relationship with the controller PCB 222 while providing the connection assembly 226 to facilitate concurrent interconnection and use of the memory PCBs 228. As such, the surface area of the controller PCB 222 can be maximized as the memory PCBs 228 are vertically stacked and supported by the support bracket 224.

Additionally, the top and side retention features 230 and 232 are illustrated engaging multiple memory PCBs 228. As can be appreciated, the support bracket 224 can be configured so that several individual top retention features 230 engage portions of the top of a memory PCB 228. Furthermore, separate top retention features 230 that are oriented on the bottom of a memory PCB 228 can further provide support to the memory PCB 228 while engaging only a localized portion of surface area of the length of the memory PCB 228. Meanwhile, a number of side retention features 232 can be included in the support bracket 224 to engage a localized portion of the side of the memory PCB 228 that is less than the overall surface area of a length of the memory PCB 228.

The configuration of the support bracket 224 with a series of alternating top and side retention features 230 and 232 can allow for absorption of turbulence and movement of the memory PCBs 228. Such energy absorption can provide a more secure data signal path from each memory PCB 228 to the controller PCB 222 through the connection assembly 226. That is, the electrical connection between each memory PCB 228 and the respective board edge connectors 234 can be reliably maintained despite motion, vibration, and abuse experienced.

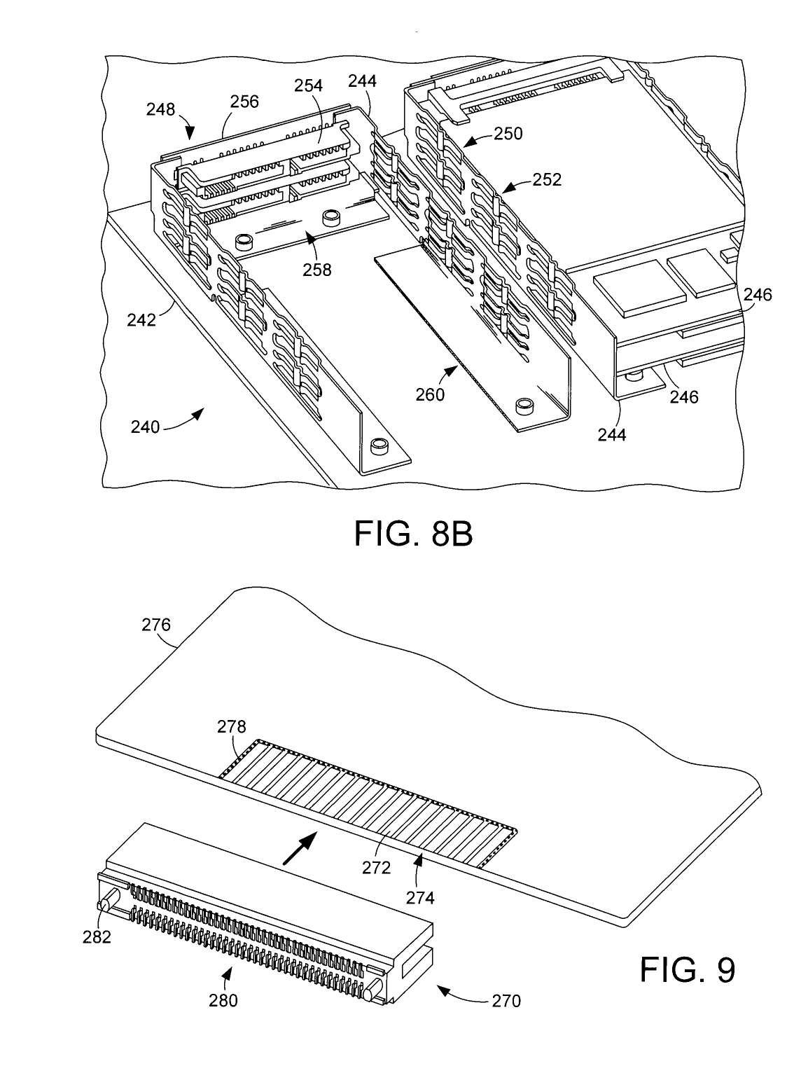

FIGS. 8A and 8B display an exemplary controller PCBA 240 in accordance with various embodiments of the present invention. In FIG. 8A, a controller PCB 242 has a plurality of support brackets 244 affixed in predetermined areas. The support brackets 244 can simultaneously support a temporarily engaged memory PCB 246 and a permanently engaged but separate connection assembly 248. The support bracket 244 can retain the memory PCB 246 through a series of top and side retention features 250 and 252 that engage localized areas of the memory PCB 242 that are less than the surface area available on one length of the memory PCB 242.

In various embodiments, the support bracket 244 can be configured to affix to the connection assembly 248 so that the board edge connector 254 is positioned towards the memory PCB 246 while the flex circuit 256 remains external to the confines of the support bracket 244. Such external configuration can be further facilitated by the inclusion of an interposer shield 258 to the support bracket 244 that creates a barrier between the interposer and the board edge connectors 254 and memory PCB 246.

The shielding of the flex circuit 256 and the external interconnecting route can provide added magnetic and electrical shielding that corresponds with a more secure data signal pathway and higher efficiency data throughput. However, such external configuration is not limited or required, and can be modified or reversed so the flex circuit 256 is completely within the bounds of the support bracket 244 without deterring from the spirit of the present invention.

FIG. 8B shows an exemplary vertical orientation of the controller PCBA 240 where the support bracket 244 concurrently retains multiple memory PCBs 246 while forming an electrical interconnection between the memory IC of each memory PCB 246 and the controller IC. The support bracket can be further configured to include stabilizing features 260 that extend into the areal extent of the memory PCB 246, but do not fully transverse a length or width of the support bracket 244. The stabilization features can allow for more efficient absorption of energy without endangering the integrity of the electrical connection between the memory IC and controller IC.

With one or more memory PCB being supported by the support bracket, the board edge connector does not require an expansive scope to provide support and maintain the memory PCB in a parallel relationship with respect to the controller PCB. FIG. 9 generally illustrates an exemplary board edge connector 270 constructed and operated in accordance with various embodiments of the present invention. The board edge connector 270 is configured to interact with one or more connection pads 272 positioned in a connection region 276 adjacent an edge of a memory PCB 276. The board edge connector 270 is further configured to engage the areal extent of the connection region 276, as displayed by the segmented line 278

In some embodiments, the board edge connector 270 only extends to the areal extent of the connection region 274 without extending into the surface area of the memory PCB 276 that is available to support components such as memory and operational components. That is, when the board edge connector 270 engages the connection region 274, no portion of the surface area of the memory PCB 276 other than the connection region 274 is occupied. Therefore, the maximum amount of surface area on the memory PCB 276 is available to support greater amounts of memory and operational components.

While the board edge connector 270 can be sized to occupy only the connection region 274, a number of individual pin connections 280 can be present to provide a connection path for each memory IC present on the memory PCB 276 as well as a number of operational connections such as, but not limited to, power and ground pathways. As such, a reduction in size of the board edge connector 270 does not limit the operational capabilities of the connector. In fact, the board edge connector 270 can have multiple sets of connection pins that correspond to different and potentially independent memory ICs.

In the exemplary embodiments shown in FIG. 9, the board edge connector 270 can simultaneously engage separate sides of the memory PCB 276 and form independent data signal paths from multiple memory IC concurrently. The board edge connector 270 can further include one or more alignment members 282 that can maintain a desired alignment between a flex circuit and the connection pins 280. The connection pins 280 can be selectively engaged and disengaged by a memory PCB to form, maintain, or break a data signal path, as desired. However, the board edge connector 270 is not limited to a particular type of data signal pathway. For example, a connective feature other than a pin can be used to form a data signal path to a host via a non-flex circuit without deterring from the spirit of the present invention.

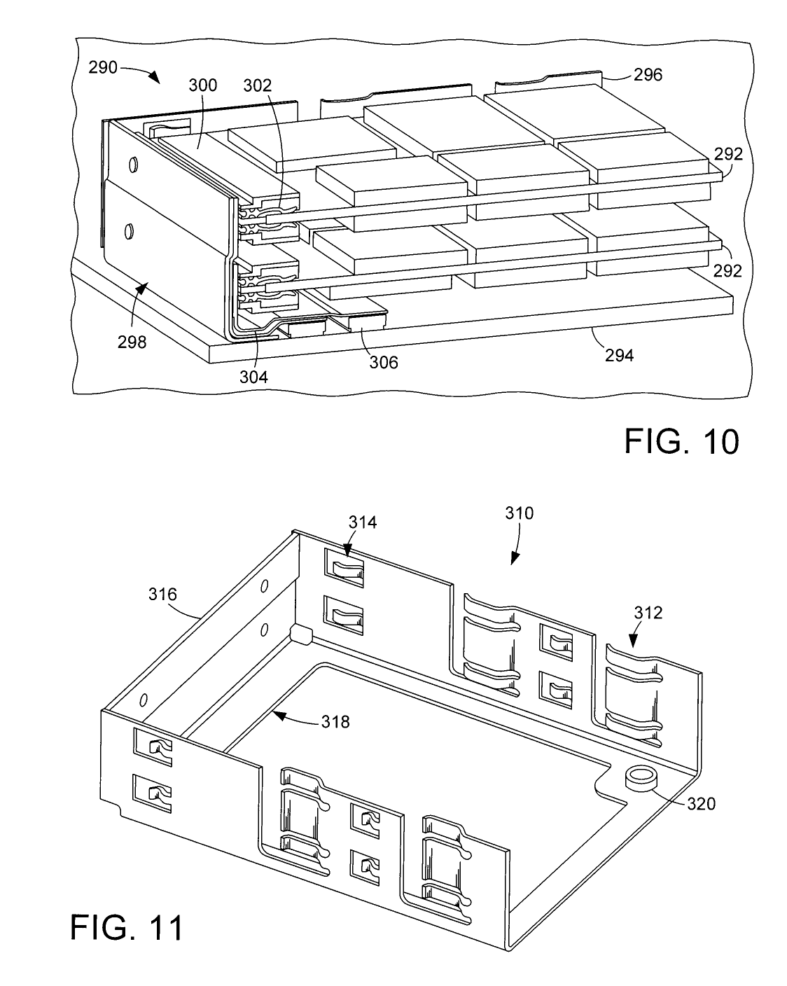

FIG. 10 generally displays a cross-section view of an exemplary controller PCBA 390 that has a plurality of memory PCBs 292 in a spaced apart, parallel relationship with a controller PCB 294. A support bracket 296 can maintain the position of the memory PCBs 292 and a connection assembly 298 that forms data signal paths between memory IC on the memory PCBs 292 and the controller PCB 294. The connection assembly 298 can have at least one board edge connector 300 that engages a portion of a memory PCB 292 with a spring member 302. In some embodiments, a number of spring members 302 are present in the board edge connector 300 and are each configured to engage a connection pad, such as the pad 272 of FIG. 9, to form a data signal path to a flexure circuit 304.

The exemplary embodiment of FIG. 10 illustrates multiple flex circuits each exclusively connected to a single memory PCB 292 and a corresponding exclusive interposer 306 positioned in the areal extent of the memory PCB 292. It can be appreciated that while two memory PCBs 292 are shown, any number of connectors, interposers, and memory PCBs can be employed, connected, and configured to form data signal pathways.

Furthermore, the support bracket 296 can be oriented to support multiple flex circuits 304 so that the circuits can traverse from a memory PCB 292 to an interposer 306 with a predetermined shape. Such predetermined shape can have an absence of right angles and a minimum amount of bends to provide a high data transfer rate between the controller PCB 294 and the memory PCB 292. It should be noted that the position and orientation of the flex circuits can be different and have various unique features, such as angles and length.

FIG. 11 provides an exemplary support bracket 310 that can be used to maintain one or more memory PCB in a predetermined relationship with a controller PCB. The support bracket 310 can have a plurality of both top and side retention features 312 and 314 that respectively engage a localized portion of a memory PCB. As shown, a top retention feature 312 can be configured to project into the areal extent and surface area of the memory PCB to secure and maintain a predetermined position. Similarly, a plurality of side retention features 314 can engage localized portions of a side of a memory PCB. Such configuration can allow for absorption of energy through displacement. That is, the retention features 312 and 314 can move while maintaining the memory PCB in a predetermined position and relationship with respect to a controller PCB.

The support bracket 310 can also provide support for a connection assembly with a cross-beam 316 that can engage a flex circuit, board edge connector, and controller PCB. The cross-beam can further include at least a lower section 318 that is adjacent the controller PCB and connects opposite sides of the support bracket 310. In some embodiments, the lower section 318 can be configured to provide an interposer region between the bracket 310 and the controller PCB that can shield the memory PCBs from the interposers.

While the support bracket 310 can provide a path for a flex circuit to connect the memory PCB to the controller PCB that is internal to the areal extent of the bracket 310, such configuration is not required or limited. For example, the cross-beam 316 can be oriented to support the connection assembly and provide an external pathway for a flex circuit. As such, a majority of a flex circuit can be shielded from the memory PCBs while providing a signal path capable of efficient data transfer rates. It can be appreciated that the support bracket 310 can be affixed to a controller PCB in a variety of manners. As shown, a positioning feature 320 can be present to provide a predetermined affixation site that can facilitate a variety of coupling means including, but not limited to, fasteners and epoxy.

Other advantages of the various embodiments presented herein will readily occur to the skilled artisan in view of the present disclosure. For example a variety of configurations of memory and controller PCBs can be constructed and controlled to efficiently manage data. Moreover, data storage devices can provide larger data capacities with improved data transfer rates with the use of more robust data signal pathways.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

What is claimed is:

1. An apparatus comprising:
a controller printed circuit board (PCB) supporting a controller integrated circuit (IC) and a support bracket;
a memory PCB supported by the support bracket in spaced apart, parallel relation to the controller PCB, the memory PCB supporting at least one memory IC and having an edge connector which engages the support bracket; and
a flex circuit that interconnects the edge connector to an interposer positioned on the controller PCB between the respective areal extent of the controller PCB and the memory PCB to form a data signal path between the memory IC and the controller IC.

2. The apparatus of claim 1, wherein data is stored in at least one solid state memory IC resident on the memory PCB.

3. The apparatus of claim 1, wherein the controller PCB is characterized as a PCIe card.

4. The apparatus of claim 1, wherein a plurality of memory PCBs are resident in the support bracket and are each in a spaced apart, parallel relationship to the controller PCB.

5. The apparatus of claim 4, wherein the memory PCBs are vertically stacked in the support bracket so to have the same areal extent with respect to the controller PCB.

6. The apparatus of claim 1, wherein the support bracket has at least one top retention feature that engages localized areas of the top of one length of a memory PCB and at least one side retention feature that engages localized areas of the side of one length of a memory PCB.

7. The apparatus of claim 6, wherein the retention features displace to absorb energy and maintain a data signal path between the memory IC and the controller IC.

8. The apparatus of claim 1, wherein the memory PCB is elevated from the controller PCB to utilize surface area of a top and bottom side of the memory PCB.

9. The apparatus of claim 1, wherein the support bracket is affixed to a connection assembly to secure the flex circuit and board edge connector in a predetermined position relative to the controller PCB.

10. The apparatus of claim 1, wherein a first memory PCB is connected to a first interposer with a first flex circuit to form a first data signal path that operates concurrently with and independently from a second data signal path formed by connecting a second memory PCB to a second interposer with a second flex circuit.

11. A data storage device comprising:
a controller printed circuit board (PCB) supporting a controller integrated circuit (IC) and a support bracket;
a memory PCB supported by the support bracket in spaced apart, parallel relation to the controller PCB, the memory PCB supporting at least one memory IC that has at least one corresponding connection pad located at an edge of the memory PCB; and
a board edge connector coupled to the connection pads of the memory PCB on a first side of the connector, while extending no farther than the areal extent of connection pads of the memory PCB, the connector affixed to the support bracket and a flex circuit on a second side of the connector to translate the connection pads to the flex circuit and form a data signal path that interconnects the memory IC and the controller IC.

12. The apparatus of claim 11, wherein the support bracket forms a recess between which houses and shields the interposer from the memory PCB.

13. The apparatus of claim 11, wherein a plurality of flex circuits each connect a memory PCB to the controller PCB to form independent data signal paths to the controller IC via different interposers.

14. The apparatus of claim 11, wherein the flex circuit houses a plurality of connective pathways along a single plane that are isolated by an polymer material that allows for movement of the flex circuit without disturbing a data signal carrying capabilities of the conductive pathways.

15. The apparatus of claim 11, wherein the board edge connector has at least one spring member that engages a connective pad resident on the memory PCB to form a data signal path from the memory IC to the board edge connector.

16. The apparatus of claim 11, wherein the board edge connector simultaneously connects to multiple memory IC by engaging connection pads on opposing top and bottom sides of the memory PCB.

17. The apparatus of claim 11, wherein the board edge connector has at least one flex circuit retention feature that engages the flex circuit and secures a connection between the board edge connector and the flex circuit.

18. An apparatus comprising:
a controller printed circuit board (PCB) supporting a controller integrated circuit (IC) and a support bracket;
a first and second memory PCB each supported by the support bracket in spaced apart, parallel relation to the controller PCB, each memory PCB supporting at least one memory IC; and
first and second flex circuits that respectively interconnect a first and second edge connector to a first and second interposer each positioned on the controller PCB between the respective areal extents of the controller PCB and the memory PCB to form independent data signal paths between the first and second memory PCBs and the controller IC.

19. The apparatus of claim 18, wherein the board edge connectors are each coupled to at least one connection pad of the memory PCB on a first side of the connector, while extending no farther than the areal extent of connection pad of the memory PCB, the connector affixed to the support bracket and a flex circuit on a second side of the connector to translate the connection pad to the flex circuit and form a data signal path that interconnects the memory IC and the controller IC.

20. The apparatus of claim 18, wherein the first memory PCB, board edge connector, and flex circuit can be selectively disconnected from the first interposer without disconnecting the second memory PCB, board edge connector, and flex circuit.
